(19) United States
(12) Patent Application Publication
(10) Pub. No.: US 2007/0125523 A1
(43) Pub. Date: Jun. 7, 2007

(54) Low profile liquid cooled server heat sink

(76) Inventors: Mohinder Singh Bhatti, Amherst, NY (US); Ilya Reyzin, Williamsville, NY (US); Luke E. O'Dwyer, Getzville, NY (US)

Correspondence Address: DELPHI TECHNOLOGIES, INC., M/C 480-410-202, PO BOX 5052, TROY, MI, 48007, US

(21) Appl. No.: 11/291,392

(22) Filed: Dec. 1, 2005

(51) Int. Cl. H05K 7/20

(52) U.S. Cl. 165/104.33; 165/80.4; 361/699

(57) ABSTRACT

A computer assembly including a casing having a bottom and end walls and side walls and a lid and a variety of computer components are supported on the bottom. A partition extends between the side walls and a plurality of fans is disposed in the partition for moving air through perforations in the end walls. A heat exchanger includes fins and each fan has a central hub and fan blades extending radially therefrom. In the embodiment of FIGS. 1 and 2, the fans move air into said fins and a flow straightener is disposed between the hub of each fan and the fins for straightening flow downstream of the hub prior to entering said fins. In the embodiment of FIGS. 3 and 4, the fans move air through the fins and into a flow deflector over each hub of the fan for diverting flow from the fins and around the hubs prior to entering the fans.

### BACKGROUND OF THE INVENTION

1. Field of the Invention

A computer assembly and more particularly to a casing enclosing a plurality of computer components with a liquid coolant system for cooling a computer chip.

2. Description of the Prior Art

The invention relates to a computer assembly including a casing having a bottom and end walls and side walls and a lid with perforations in the end walls for air flow through the casing to cool the computer components. A partition extends between the side walls and spaced from the end walls for establishing a first compartment on one side and a second compartment on the other side and a plurality of fans are disposed in the partition for moving air through the perforations and through the compartments. A heat exchanger is disposed in the second compartment and includes fins disposed extending parallel to the side walls and the fans each have a central hub and fan blades extending radially therefrom.

### SUMMARY OF THE INVENTION AND ADVANTAGES

The invention provides for a flow control disposed between the fins and the hub of each fan for reconciling air flow around the hub with straight flow through the fins.

### BRIEF DESCRIPTION OF THE DRAWINGS

Other advantages of the present invention will be readily appreciated, as the same becomes better understood by reference to the following detailed description when considered in connection with the accompanying drawings wherein:

FIG. 1 is a perspective view of a first embodiment of the invention;

FIG. 2 is a perspective view of the heat exchanger and fan arrangement of the first embodiment;

FIG. 3 is a perspective view of a second embodiment of the invention; and

FIG. 4 is a perspective view of the heat exchanger and fan arrangement of the second embodiment.

### DETAILED DESCRIPTION OF THE INVENTION

Referring to the figures, wherein like numerals indicate corresponding parts throughout the several views, a computer assembly 20 is generally shown.

The assembly 20 includes a casing 22 generally indicated which is made up of a bottom 24 and end walls 26 and side walls 28 and a lid 30. The end walls 26 have perforations 32 therein for air flow through the casing 22.

A plurality of computer components are supported on the bottom 24, including various circuit boards 34 and electronic boxes 36.

A partition 38 extends between the side walls 28 and is spaced from the end walls 26 for establishing a first compartment on one side and a second compartment on the other side.

A cold plate 40 is disposed on the bottom 24 in the first compartment and an electronic chip is disposed on the cold plate 40 for cooling by the cold plate 40. More specifically, a liquid coolant is circulated through the cold plate 40 by a pump 42 disposed on the bottom 24 in the second compartment. A heat exchanger 44 is generally indicated and extends along and adjacent to the partition 38 and includes coolant tubes 46 and fins 48 disposed about the tubes and extending parallel to the side walls 28. The fins 48 establish a direction of flow perpendicular to the end walls 26 and parallel to the side walls 28, i.e., straight flow. A plurality of coolant conduits 50 interconnect or establish fluid communication between the cold plate 40 and the pump 42 and the tubes of the heat exchanger 44 for circulating coolant fluid through the pump 42 and the cold plate 40 and the heat exchanger 44 for cooling the coolant fluid in the heat exchanger 44 and extracting heat from the electronic chip at the cold plate 40.

The partition 38, via a plurality of housings, defines a plurality of opening disposed in side by side relationship to one another along the partition 38. An array of fans are disposed in side-by-side relationship to one another in the openings defined by the housings in the partition 38 for moving air through the perforations 32 in the end walls 26 and through the compartments. Each of the fans has a central hub 52 and fan blades extend radially therefrom, each hub 52 being centrally supported in an opening by a plurality of spokes 54 extending radially from each hub 52.

The heat exchanger 44 extends along and adjacent to the array of fans in the second compartment.

The invention includes a flow control disposed between the array of fans and the fins 48 for reconciling air flow around each of the hubs 52 with straight flow through the fins 48.

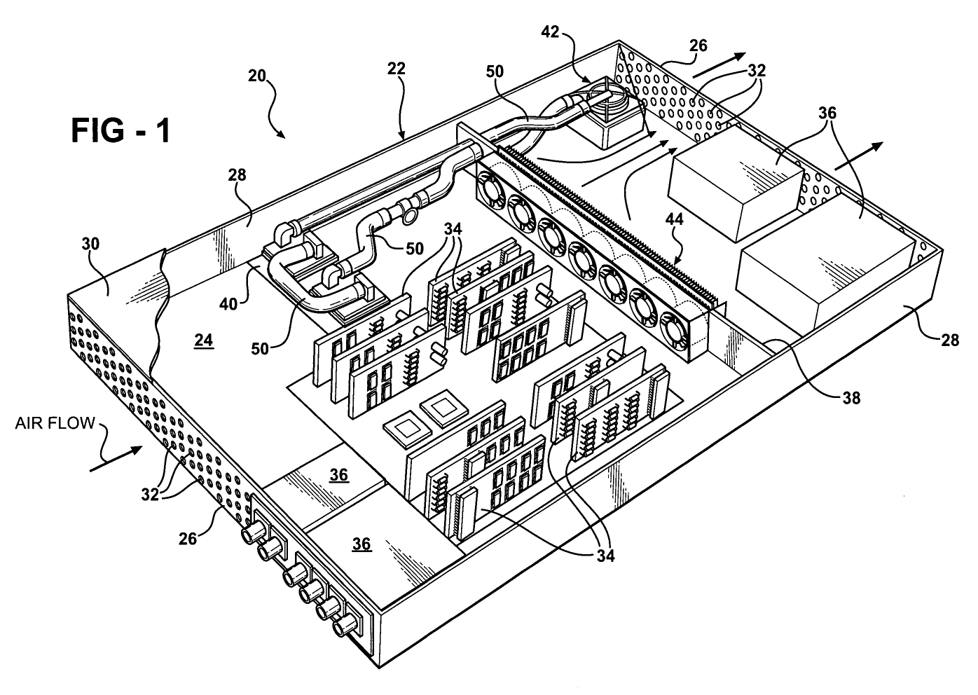

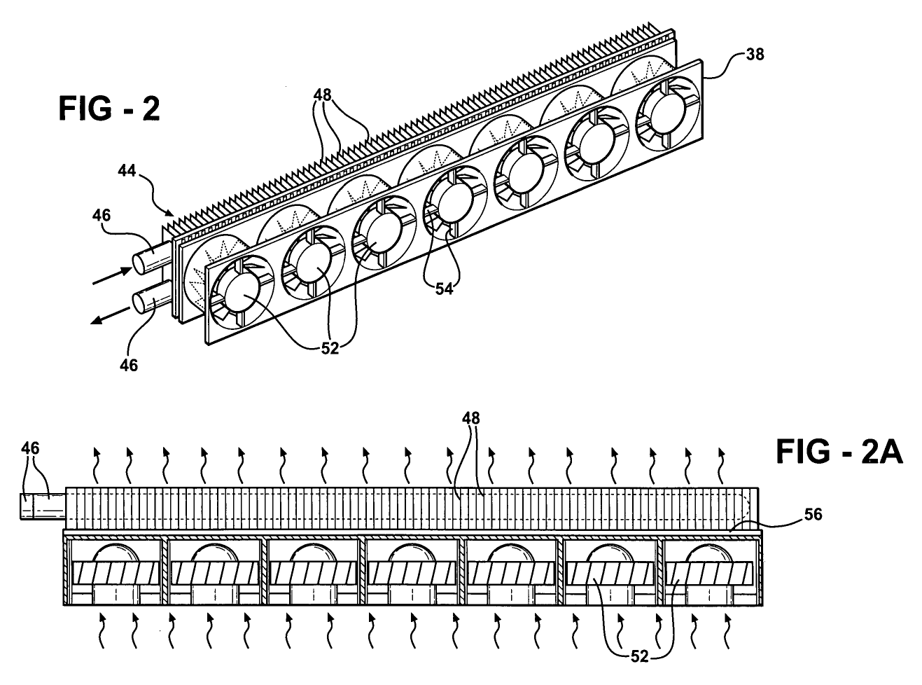

In the embodiment of FIGS. 1 and 2, the fans move air through the first compartment and into the fins 48 in the second compartment and the flow control includes a flow straightener 56 between the hub 52 of the fan and the fins 48 for straightening flow downstream of the hub 52 prior to entering the fins 48.

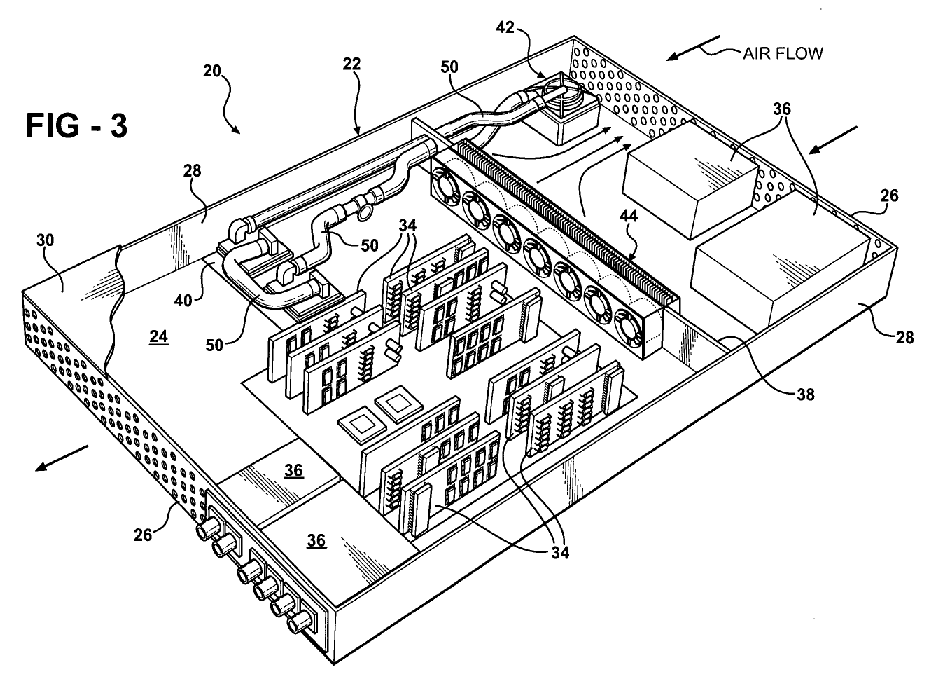

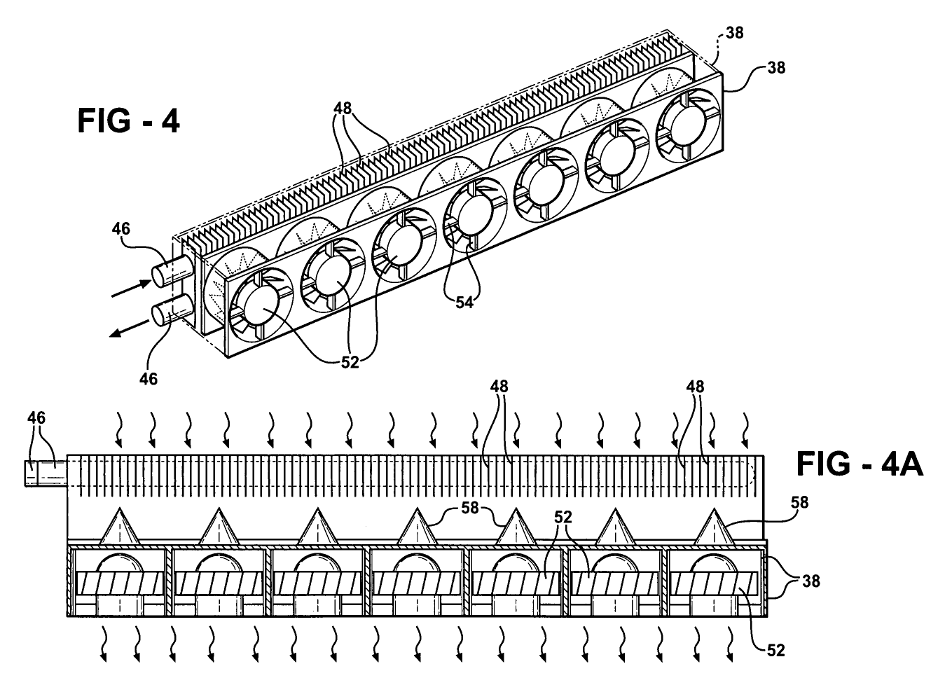

In the embodiment of FIGS. 3 and 4, the fans move air through the second compartment and through the fins 48 and into the first compartment and the flow control includes a flow deflector 58 over the hub 52 of the fan for diverting flow from the fins 48 and around the hub 52 prior to entering the fan. The flow diverter takes the form of a cone having its base disposed over the hub 52.

Obviously, many modifications and variations of the present invention are possible in light of the above teachings. The invention may be practiced otherwise than as specifically described within the scope of the appended claims, wherein that which is prior art is antecedent to the novelty set forth in the “characterized by” clause. The novelty is meant to be particularly and distinctly recited in the “characterized by” clause whereas the antecedent recitations merely set forth the old and well-known combination in which the invention resides. These antecedent recitations should be interpreted to lid 30 any combination in which the incentive novelty exercises its utility. In addition, the reference numerals in the claims are merely for convenience and are not to be read in any way as limiting.

1. A computer assembly comprising;
a casing having a bottom and end walls and side walls and a lid,
said end walls having perforations therein for air flow through said casing,
computer components supported on said bottom,
a partition extending between said side walls and spaced from said end walls for establishing a first compartment on one side and a second compartment on the other side,
a fan disposed in said partition for moving air through said perforations and through said compartments,
a heat exchanger in said second compartment and including fins disposed extending parallel to said side walls,
said fan having a central hub and fan blades extending radially therefrom, and
characterized by a flow control disposed between said fins and said hub of said fan for reconciling air flow around said hub with straight flow through said fins.

2. An assembly as set forth in claim 1 wherein said fan moves air through said first compartment and into said fins in said second compartment and said flow control includes a flow straightener between said hub of said fan and said fins for straightening flow downstream of said hub prior to entering said fins.

3. An assembly as set forth in claim 1 wherein said fan moves air through said second compartment and through said fins and into said first compartment and said flow control includes a flow deflector over said hub of said fan for diverting flow from said fins and around said hub prior to entering said fan.

4. A computer assembly comprising;
a casing having a bottom and end walls and side walls and a lid,
said end walls having perforations therein for air flow through said casing,
computer components supported on said bottom,
a partition extending between said side walls and spaced from said end walls for establishing a first compartment on one side and a second compartment on the other side,
a cold plate disposed on said bottom in said first compartment,
an electronic chip disposed on said cold plate for cooling by said cold plate,
a pump disposed on said bottom in said second compartment,
said partition defining a plurality of opening disposed in side by side relationship to one another,
an array of fans disposed in side-by-side relationship to one another in said openings in said partition for moving air through said perforations and through said compartments,
a heat exchanger extending along said array of fans in said second compartment and including coolant tubes and fins disposed about said tubes and extending parallel to said side walls,
coolant conduits interconnecting said cold plate and said pump and said tubes of said heat exchanger for circulating coolant fluid through said pump and said cold plate and said heat exchanger for cooling the coolant fluid in said heat exchanger and extracting heat from said electronic chip at said cold plate,
each of said fans having a central hub and fan blades extending radially therefrom,
a plurality of spokes in each of said openings extending radially from said hub for supporting each fan in one of said openings, and
characterized by a flow control disposed between said array of fans and said fins for reconciling air flow around each of said hubs with straight flow through said fins.

5. An assembly as set forth in claim 4 wherein said fan moves air through said first compartment and into said fins in said second compartment and said flow control includes a flow straightener between said hub of said fan and said fins for straightening flow downstream of said hub prior to entering said fins.

6. An assembly as set forth in claim 4 wherein said fan moves air through said second compartment and through said fins and into said first compartment and said flow control includes a flow deflector over said hub of said fan for diverting flow from said fins and around said hub prior to entering said fan.
